(19) United States
(12) Patent Application Publication
(10) Pub. No.: US 2009/0206873 A1
(43) Pub. Date: Aug. 20, 2009

(54) DATA OUTPUT DRIVER

(75) Inventor: Jun Gi Choi, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/329,081

(22) Filed: Dec. 5, 2008

(30) Foreign Application Priority Data
Feb. 20, 2008 (KR) 10-2008-0015207

(51) Int. Cl. H03K 17/16; H03K 19/0175

(52) U.S. Cl. 326/27; 326/26; 326/83

(57) ABSTRACT

A data output driver device includes a noise detecting unit configured to output a noise detection signal to detect variations of power supply voltage due to noise, and a driver circuit unit configured to drive and output data with the variable driving capability in response to the noise detection signal.

### CROSS-REFERENCES TO RELATED APPLICATION

The present application claims priority under 35 U.S.C. §119(a) to Korean application number 10-2008-0015207, filed on Feb. 20 2008, in the Korean Intellectual Property Office, which is incorporated herein in its entirety by reference as if set forth in full.

### BACKGROUND

1. Technical Field

The embodiments described there relate to an output driver, and more particularly, to a data output driver for a semiconductor integrated circuit (IC).

2. Related Art

Generally, a data output driver includes buffers IV1 and IV2, a first transistor M1 whose source is connected to an external voltage (VDD) terminal, and a second transistor M2 whose source is connected to a ground voltage (VSS) terminal, as shown in FIG. 1. The data output driver that receives data (DATA) drives either HIGH level data though the first transistor M1 or LOW level data through the second transistor M2.

In many instances, an external voltage VDD is input through an exposed pin of a semiconductor integrated circuit and an inductance may exist on transmission path connected to the pin, wherein the external voltage VDD contains noise, especially low frequency noise. Due to the low frequency noise, levels of the external voltage VDD can greatly vary. When a data output driving operation is performed using the external voltage VDD having the noise, the level of output data is unstable and, moreover, the slew rate of output data abnormally varies. Accordingly, as the levels of the external voltage VDD vary due to the noise, integrity of the output data decreases due to distortions of the output data directly related to the noise. Thus, due to the distorted output data, there exists a high probability that critical operation errors will occur in the semiconductor integrated circuit, in particular, where low voltage and high speed operation is needed.

### SUMMARY

A data output driver capable of preventing abnormal variation of the level and slew rate of output data due to noise is described herein.

In one aspect, a data output driver includes a noise detecting unit configured to output a noise detection signal to detect variations of power supply voltage due to noise, and a driver circuit unit configured to drive and output data with the variable driving capability in response to the noise detection signal.

In another aspect, a data output driver includes a noise detecting unit configured to output noise detection signal to detect variations of a power supply voltage due to noise, at least one first driver configured to drive and output received data through a data output terminal, and at least one second driver configured to drive and output the received data through the data output terminal according to the noise detection signal.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a schematic circuit diagram of a conventional data output driver of a semiconductor integrated circuit;

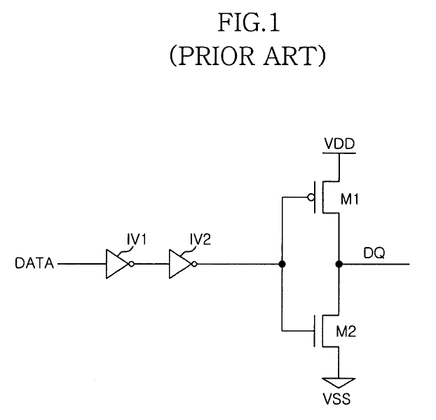

FIG. 2 is a schematic circuit diagram of an exemplary data output driver according to one embodiment;

FIG. 3 is a schematic circuit diagram of an exemplary noise detecting unit of FIG. 2 according to one embodiment; and

FIG. 4 is an output simulation waveform of an exemplary data output driver according to one embodiment.

### DETAILED DESCRIPTION

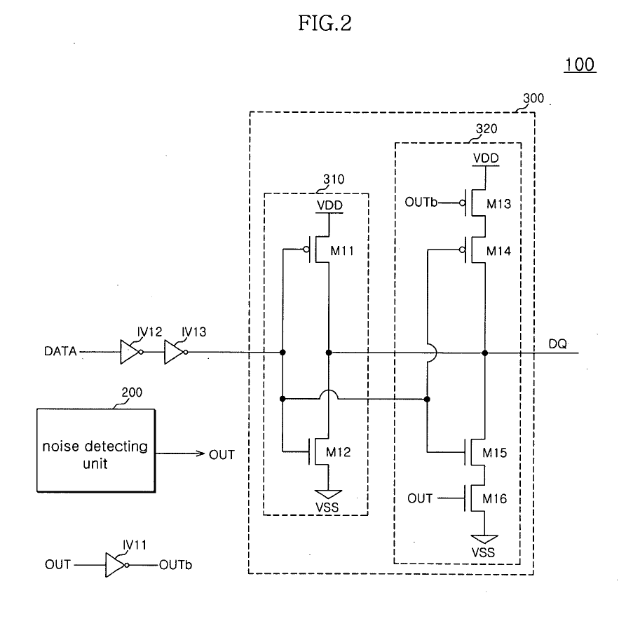

FIG. 2 is a schematic circuit diagram of an exemplary data output driver according to one embodiment. Referring to FIG. 2, a data output driver 100 of a semiconductor integrated circuit can be configured to include first to third inverters IV11 to IV13, a noise detecting unit 200, and a driver circuit unit 300. For example, the data output driver 100 may be connected to a semiconductor integrated circuit (IC) to drive the semiconductor IC.

The first inverter IV11 can arranged to inversely output a noise detection signal ‘OUT’ through the noise detecting unit 200. In addition, the second and third inverters IV12 and IV13 can buffer a data signal ‘DATA’ so as to transmit the drive circuit unit 300 with a substantially stable signal level.

The drive circuit unit 300 can be configured to include a first driver 310 and a second driver 320, wherein the drive circuit unit 300 can use an external voltage VDD as a power supply voltage. The first driver 310 can be configured to include a first transistor M11 to which an external voltage terminal VDD is connected and a second transistor M12 to which a ground voltage terminal VSS is connected. The data signal ‘DATA’ can be commonly provided as input to the gate terminals of the first and second transistors M11 and M12.

The second driver 320 can be configured to include a third transistor M13 having a gate terminal that receives an inverted noise detection signal ‘OUTb’ and a source terminal that is connected to an external voltage terminal VDD. A fourth transistor M14 can have a gate terminal that receives the data signal ‘DATA’, a source terminal that is connected to the drain terminal of the third transistor M13, and a drain terminal that is connected to a data output terminal DQ. A fifth transistor M15 can have a gate terminal that receives the data signal ‘DATA’ and a drain terminal that is connected to the data output terminal DQ. A sixth transistor M16 can have a gate terminal that receives the noise detection signal ‘OUT’, a drain terminal that is connected to the source of the fifth transistor M15, and a source terminal that is connected to a ground voltage terminal VSS. Although the drive circuit unit 300 is shown to be configured having the first driver 310 and the second driver 320, additional drivers may be included.

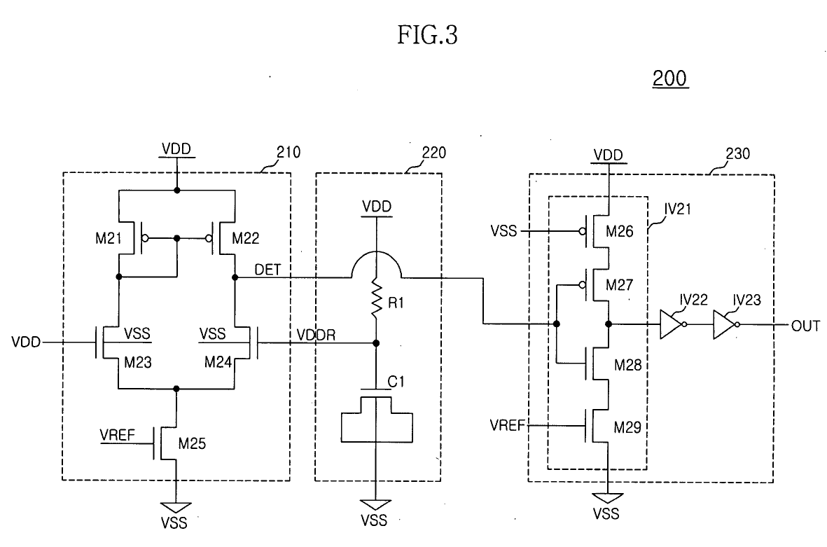

FIG. 3 is a schematic circuit diagram of an exemplary noise detecting unit of FIG. 2 according to one embodiment. Referring to FIG. 3, the noise detecting unit 200 can be configured to include a differential amplifying unit 210, a filter circuit unit 220, and a buffer circuit unit 230. The differential amplifying unit 210 can output a detection signal ‘DET’ having different output levels depending on whether the external voltage VDD is higher or lower than a reference voltage VDDR. When the external voltage VDD is higher than the reference voltage VDDR, the differential amplifying unit 210 can output the detection signal ‘DET’ at a HIGH level. Conversely, the differential amplifying unit 210 can output the detection signal ‘DET’ at a LOW level. The differential amplifying unit 210 can be configured to include first to fifth transistors M21 to M25.

The filter circuit unit 220 can be configured to generate the reference voltage VDDR, and to remove noise components of the external voltage VDD. The reference voltage VDDR can be generated via the filter circuit unit 220 in order to set a normalized standard level of a noiseless external voltage VDD. The filter circuit unit 220 can be configured to include a resistor R1 and a capacitor C1 disposed between the external voltage terminal VDD and the ground voltage terminal VSS. The reference voltage VDDR can be output through a common node of the resistor R1 and capacitor C1. The buffer circuit unit 230 can be configured to buffer the detection signal ‘DET’ and produce the noise detection signal ‘OUT’. For example, the buffer circuit unit 230 can include first to third inverters IV21 to IV23, wherein the first inverter IV21 can include sixth to ninth transistors M26 to M29. The sixth and ninth transistors M26 and M29 can function as load elements to not include noise components in an output signal of a buffer circuit unit 230, i.e., the noise detection signal ‘OUT’.

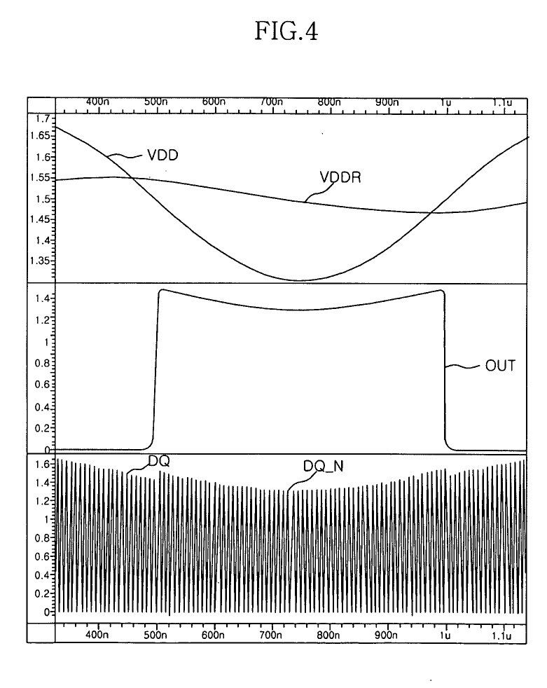

FIG. 4 is an output simulation waveform of an exemplary data output driver of a semiconductor integrated circuit according to one embodiment. In FIG. 4, waveforms of an external voltage VDD and a reference voltage VDDR are shown. Referring to FIG. 4, while an external voltage VDD can vary due to the presence of noise components, i.e., voltage drops of under about 1.5V during some intervals, the reference voltage VDDR produced by removing noise of the external voltage VDD using the filter circuit unit 220 (in FIG. 3) can constantly maintain a substantially stable level in contrast to simply using the external voltage VDD alone.

During an interval where the level of an external voltage VDD is higher than an interval level of a reference voltage VDDR, the differential amplifying unit 210 ( in FIG. 3) can be configured to output the detection signal ‘DET’ at a HIGH level. However, during another interval where the level of an external voltage VDD is lower than an interval level of a reference voltage VDDR, the differential amplifying unit 210 (in FIG. 3) can output the detection signal ‘DET’ at a LOW level.

In FIG. 3, the buffer circuit unit 230 can invert the detection signal ‘DET’ to a level opposite of its original state in order to output a noise detection signal ‘OUT’. As shown in FIG. 4, the noise detection signal ‘OUT’ can be inactivated to a LOW level during an interval where the level of an external voltage VDD is higher than an interval level of a reference voltage VDDR. Conversely, the noise detection signal ‘OUT’ can be activated to a HIGH level during another interval where the level of an external voltage VDD is lower than an interval level of a reference voltage VDDR.

When the noise detection signal ‘OUT’ is inactivated to a LOW level, the level of an external voltage VDD is substantially high enough to enable stable output data driving with the driving capability of only the first driver 310 (in FIG. 2). Conversely, when the noise detection signal ‘OUT’ is activated to a HIGH level, the level of an external voltage VDD is low, whereby stable output data driving with the driving capability of only the first driver 310 (in FIG. 2) is not enabled. Thus, when the noise detection signal ‘OUT’ is activated, simultaneous operation of the first driver 310 and the second driver 320 can improve data driving capability and stabilize output level and slew rate of output data.

For example, when the noise detection signal ‘OUT’ is inactivated to a LOW level, the third and sixth transistors M13 and M16 of second driver 320 (in FIG. 2) can be inactivated to stop their operation. Accordingly, only the first driver 310 can drive the data output terminal DQ in accordance with the level of received data signal ‘DATA’ by operation of the first and second transistors M11 and M12.

In FIG. 2, the first and second transistors M11 and M12 of the first driver 310 can be activated regardless of the noise detection signal ‘OUT’. Thus, the first driver 310 and the second driver 320 can simultaneously drive the data output terminal DQ according to the level of the received data signal ‘DATA’ by operation of the first and second transistors M11 and M12. Accordingly, improvement of the data driving capability obtained by simultaneously operating the first driver 310 and the second driver 320 makes it possible to drive the data output terminal DQ at a substantially stable level, even if the level of the external voltage VDD is relatively low. While the output data DQ is substantially unstable during an interval where the level of the external voltage VDD is relatively low, the output data ‘DQ_N’ can maintain a substantially stable level during the same interval where the level of the external voltage VDD is relatively low due to the compensation provided by operation of the second driver 320.

While certain embodiments have been described above, it will be understood that the embodiments described are by way of example only. Accordingly, the and method described herein should not be limited based on the described embodiments. Rather, the s and methods described herein should only be limited in light of the claims that follow when taken in conjunction with the above description and accompanying drawings.

What is claimed is:

1. A data output driver comprising:
a noise detecting unit configured to output a noise detection signal to detect variations of power supply voltage due to noise; and
a driver circuit unit configured to drive and output data with the variable driving capability in response to the noise detection signal.

2. The data output driver of claim 1, wherein the noise detecting unit is configured to receive an external voltage as the power supply voltage.

3. The data output driver of claim 1, wherein the noise detecting unit comprises:
a differential amplifying unit configured to compare the power supply voltage to a reference voltage to activate the noise detection signal; and
a filter circuit unit configured to generate the reference voltage by removing noise components of the power supply voltage.

4. The data output driver of claim 3, wherein the differential amplifying unit is configured to activate the noise detection signal when the level of the power supply voltage is lower than the level of the reference voltage.

5. The data output driver of claim 3, wherein the filter circuit unit is configured to include a resistor and a capacitor between the external voltage terminal and a ground voltage terminal, and to output the reference voltage through a common node of the resistor and the capacitor.

6. The data output driver of claim 3, further comprising a buffer circuit unit configured to buffer and output the noise detection signal.

7. The data output driver of claim 6, wherein the buffer circuit unit is configured so that each of a power supply voltage terminal and a ground terminal is connected to load elements for removing noise components of output signal.

8. The data output driver of claim 1, wherein the drive circuit unit includes a plurality of driver circuits receive the data in common.

9. The data output driver of claim 8, wherein at least one of the plurality of the driver circuits operates in response to the noise detection signal.

10. The data output driver of claim 8, wherein a first group of the plurality of the driver circuits operate in response to the noise detection signal and a second group of the plurality of driver circuits operate in response to the level of the data.

11. The data output driver of claim 8, wherein the plurality of driver circuits that operate in response to the noise detection signal includes:
a first switching device connected to the power supply voltage terminal and is activated in response to the noise detection signal;
a second switching device connected to a ground voltage terminal and is activated in response to the noise detection signal;
a third switching device connected between the first switching device and data output terminal and is activated according to the level of the data; and
a fourth switching device connected between the second switching device and the data output terminal and is activated according to the level of the data.

12. A data output driver comprising:
a noise detecting unit configured to output noise detection signal to detect variations of a power supply voltage due to noise;
at least one first driver configured to drive and output received data through a data output terminal; and
at least one second driver configured to drive and output the received data through the data output terminal according to the noise detection signal.

13. The data output driver of claim 12, wherein the noise detecting unit includes:
a differential amplifying unit configured to compare the power supply voltage to a reference voltage to activate the noise detection signal; and
a filter circuit unit configured to generate the reference voltage by removing noise components of the power supply voltage.

14. The data output driver of claim 13, wherein the filter circuit unit includes a resistor and a capacitor disposed between the external voltage terminal and a ground voltage terminal, and outputs the reference voltage through a common node of the resistor and the capacitor.

15. The data output driver of claim 13, further comprising a buffer circuit unit configured to buffer and output the noise detection signal.

16. The data output driver of claim 12, wherein the at least one second driver, includes:
a first switching device connected to the power supply voltage terminal and is activated in response to the noise detection signal;
a second switching device connected to a ground voltage terminal and is activated in response to the noise detection signal;
a third switching device connected between the first switching device and the data output terminal and is activated according to the level of the data; and
a fourth switching device connected between the second switching device and the data output terminal and is activated according to the level of the data.
